(19) United States
(12) Patent Application Publication
(10) Pub. No.: US 2024/0427061 A1
(43) Pub. Date: Dec. 26, 2024

(54) PROTECTIVE COATING FOR IMAGE SENSORS

(71) Applicant: Salvo Technologies, Inc., Largo, FL (US)

(72) Inventors: Hugh Garvey, Seminole, FL (US); Brion M. Deffely, Largo, FL (US)

(21) Appl. No.: 18/744,801

(22) Filed: Jun. 17, 2024

Related U.S. Application Data
(60) Provisional application No. 63/521,892, filed on Jun. 20, 2023.

(51) Int. Cl. G02B 1/14; C23C 14/10

(52) U.S. Cl. CPC G02B 1/14; C23C 14/10

(57) ABSTRACT

The surface of an image sensor is coated in a substance, such as Silicon Dioxide (SiO2), to protect the image sensor from damage when a sample is put in direct contact with the imaging surface to, for instance, collect an image of the sample by direct imaging means is disclosed.

### CROSS-REFERENCE TO RELATED APPLICATION

The present application claims the benefit of previously filed co-pending Provisional Patent Application, Ser. No. 63/521,892 filed on Jun. 20, 2023.

### FIELD OF THE INVENTION

The method of this disclosure belongs to the field of high performance imaging. More specifically it is a method of application of a protective coating on image sensors.

### BACKGROUND OF THE INVENTION

In general the light used to form an image is conveyed to an image sensor through an optic or a series of optics to form an image on the image sensor surface which may then be detected by the image sensor and turned into an electronic representation. In certain types of applications though it is preferable to form the image without the use of conventional optics. However, the surface of an image sensor is quite delicate and so arranging for the subject to be in contact with the image plane without damaging the structures on the image sensor itself can be quite problematical. One method used to circumvent this problem is to bond a fiber optic faceplate (often FOP) to the image sensor. The image plane is then transferred through the FOP and the outer surface of the FOP becomes the imaging surface which is quite robust. Damage to the image sensor can then be avoided and the FOP can be wiped clean for further imaging attempts.

However, the resolution of an FOP is limited by the size of the fibers used to create the faceplate the minimum size for which is limited by the numerical aperture of the fiber which decreases as the size is reduced reaching a practical limit at about 2-3 um for glass fibers. More recent plastic-based FOP's have a higher resolution limit but are less robust and prone to attack by certain chemicals. But even these FOPs degrade the imaging performance of the image sensor to some extent, especially as the pixel size on the image sensor is reduced, which is often preferable in high performance direct imaging applications.

The invention of this disclosure circumvents the need for an FOP or any other type of optic in direct imaging applications. Rather than installing a FOP on the image sensor a high-performance coating is applied, such as SiO2, which is optically transparent, can be deposited very uniformly and with a high degree of precision with respect to the thickness, but also forms a protective layer on the image sensor to allow direct contact imaging applications to be performed without damaging the imaging surface.

### BRIEF SUMMARY OF THE INVENTION

The method of this disclosure belongs to the field high performance imaging. More specifically in the disclosed invention the surface of an image sensor is coated with a substance, such as Silicon Dioxide (SiO2), to protect the image sensor from damage when a sample is put in direct contact with the imaging surface to, for instance, collect an image of the sample by direct imaging means.

### DESCRIPTION OF THE PREFERRED EMBODIMENT

As discussed above the method of this disclosure circumvents the need for the FOP or any other type of optic in direct imaging applications. Rather than installing a FOP on the image sensor a high-performance coating is applied, such as SiO2, which is optically transparent, can be deposited very uniformly and with a high degree of precision with respect to the thickness, but also forms a protective layer on the image sensor to allow direct contact imaging applications to be performed without damaging the imaging surface.

More specifically in the preferred embodiment method of this invention a coating of Silicon Dioxide (SiO2) is deposited on the image sensor very uniformly and with a high degree of precision with respect to the thickness of the coating is created by ensuring that the pump-down schedule is long enough to make sure there are no residuals coming from the image sensor/printed circuit board assembly which might affect the coating process or coating itself.

Also one could potentially sputter the coating on the device rather than use an evaporative process, which would lead to an ˜25% harder coating-still using SiO2. Another embodiment altogether would be to use a Diamond-Like Coating such as those used to make very hard films on optical surfaces using carbon.

Since certain changes may be made in the above described method of using protective coating on an image sensor without departing from the scope of the invention herein involved, it is intended that all matter contained in the description thereof shall be interpreted as illustrative and not in a limiting sense.

What is claimed is:

1. A protective layer to allow direct contact imaging applications to be performed without damaging the imaging surface on an image sensor by applying a high-performance coating which is optically transparent and that is deposited very uniformly and with a high degree of precision with respect to the thickness.

2. The protective layer of claim 1 wherein said high-performance coating is SiO2 using an evaporative process.

3. The protective layer of claim 2 wherein said protective layer is sputter coated on the device.

4. A protective layer to allow direct contact imaging applications to be performed without damaging the imaging surface on an image sensor by applying a Diamond-Like Coating such as those used to make very hard films on optical surfaces using carbon.
